(19) United States
(12) Patent Application Publication
(10) Pub. No.: US 2010/0079950 A1
(43) Pub. Date: Apr. 1, 2010

(54) Radiating Fin and Thermal Module Formed Therefrom

(75) Inventors: Xiang Yu Wen, Shenzhen City (CN); Xin Liang Zhu, Shenzhen City (CN)

Correspondence Address: NIKOLAI & MERSEREAU, P.A., 900 SECOND AVENUE SOUTH, SUITE 820, MINNEAPOLIS, MN, 55402, US

(73) Assignee: Asia Vital Components (Shen Zhen) Co., Ltd., Shenzhen City (CN)

(21) Appl. No.: 12/243,433

(22) Filed: Oct. 1, 2008

(51) Int. Cl. H05K 7/20

(52) U.S. Cl. 361/697; 361/690

(57) ABSTRACT

A thermal module includes a base for contacting with a heat-producing element, a radiating fin assembly consisting of a plurality of stacked radiating fins, a heat pipe having an end connected to the base and the other end extended through the radiating fin assembly, and a fan mounted to one side of the radiating fin assembly. Each of the radiating fins includes a flat main body having a first and a second transverse edge, and at least one projected portion provided on at least one of the first and the second transverse edge. Positions on the first and/or the second transverse edge without the projected portion are open portions. The projected portions on two adjacent radiating fins are staggered, so that a plurality of expanded heat dissipating spaces can be formed on the radiating fin assembly to enable smooth flowing of heat-carrying airflows and upgraded heat dissipating efficiency.

### FIELD OF THE INVENTION

The present invention relates to a radiating fin and a thermal module formed therefrom, and more particularly to a radiating fin and a thermal module formed therefrom that enable smooth flowing of heat-carrying airflows and upgraded heat dissipating efficiency.

### BACKGROUND OF THE INVENTION

With the quick development in the field of electronic technologies, electronic elements are designed to operate at a largely increased speed and accordingly, would produce a large amount of heat during the operation thereof. Therefore, the demands for functionally improved heat sink are also increased.

A conventional way of enhancing the heat dissipating function of a heat sink is to use a stack-type radiating fin assembly for it. Many researches have been conducted to develop improved radiating fins, and it has become one of the most important issues in the industrial field to develop a high-performance heat sink.

Taking a computer as an example, when the computer is started, a central processing unit (CPU) inside the computer will operate at high speed and produce a large amount of heat. When the heat produced by the CPU gradually increases, the computer tends to have reduced running speed. When the heat accumulated in the computer exceeds an allowable high limits thereof, unexpected shutdown of the computer or even a burned-out CPU would occur. Moreover, to solve the problem of electromagnetic radiation, most of the important components of the computer are enclosed in a case. The case also prevents the heat produced by the CPU and other heat-producing elements from quickly dissipating into ambient air. Therefore, it is desirable to develop an effective way for quickly conducting and dissipating the heat produced by the CPU and other heat-producing electronic elements in the case.

FIG. 1 is a perspective view of a conventional thermal module, which includes a radiating fin assembly 1 consisting of a plurality of stacked radiating fins 11, and a fan 2 mounted to one side of the radiating fin assembly 1. Each of the radiating fins 11 is formed by cutting a thin metal sheet into a desired shape. The radiating fin 11 has a top surface 11a and is formed at two opposite ends with a downward bent skirt portion 111 each. When the radiating fins 11 are stacked, the skirt portions 111 of an upper radiating fin 11 are rested on the top surface 11a of a lower radiating fin 11, so that a heat dissipating space 112 is formed between any two adjacent radiating fins 11 in the radiating fin assembly 1. The fan 2 is mounted to one side of the radiating fin assembly 1 facing toward the heat radiating spaces 112 to blow airflows through the radiating fin assembly 1 via the heat dissipating spaces 112, so as to carry away heat absorbed by the radiating fin assembly 1. Since the radiating fins 11 are densely stacked to form the radiating fin assembly 1, the heat dissipating spaces 112 formed between the adjacent radiating fins 11 are narrow and small, preventing the airflows from smoothly flowing through the radiating fin assembly 1 at high flowing efficiency. As a result, the thermal module provides only a low heat dissipating efficiency.

In brief, the thermal module formed from the conventional radiating fins has the following disadvantages: (1) having very narrow and small heat dissipating spaces; (2) having poor heat exchange efficiency; and (3) providing low heat dissipating efficiency.

It is therefore tried by the inventor to develop an improved radiating fin for forming an improved thermal module to overcome the disadvantages in the conventional thermal module.

### SUMMARY OF THE INVENTION

A primary object of the present invention is to provide a radiating fin being formed on at least one transverse edge with spaced projected portions. When a plurality of the radiating fins are stacked to form a radiating fin assembly, the projected portions on two adjacent radiating fins are staggered, so that expanded heat dissipating spaces can be formed on the radiating fin assembly to enable smooth flowing of heat-carrying airflows and upgraded heat dissipating efficiency.

To achieve the above and other objects, the radiating fin according to the present invention includes a flat main body having a first transverse edge and a second transverse edge, and at least one horizontally outward projected portion selectively provided on at least one of the first and the second transverse edge, such that at least one open portion is formed along the first or the second transverse edge at a position where the projected portion is not formed. A plurality of the radiating fins can be stacked to form a radiating fin assembly. The projected portions on a first radiating fin are in a staggered relation to the projected portions on an adjacent second radiating fin, so that expanded heat dissipating spaces can be formed on the radiating fin assembly between a first and a third radiating fin thereof.

The radiating fin assembly together with a base, at least one heat pipe, and a fan can form a thermal module. The base is in direct contact with a heat source to transfer the heat to the radiating fin assembly via the heat pipe. The fan blows airflows through the radiating fin assembly to carry away heat absorbed by the radiating fins. With the staggered projected portions on the radiating fin assembly, expanded heat dissipating spaces can be provided on the radiating fin assembly to enable smooth flowing of the heat-carrying airflows and upgraded heat dissipating efficiency.

In conclusion, the present invention provides the following advantages: (1) enabling smooth flowing of the heat-carrying airflows through the radiating fin assembly at high flowing efficiency; (2) providing increased heat radiating area; (3) enabling reduced resistance to the heat-carrying airflows; and (4) providing upgraded heat dissipating efficiency.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a conventional thermal module;

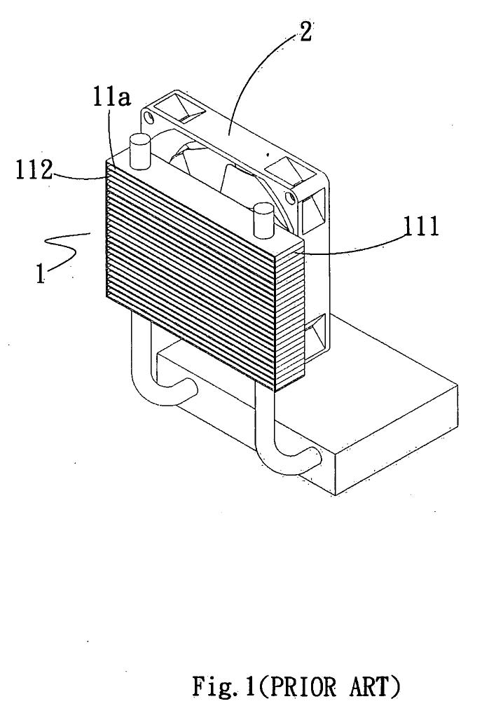

FIG. 2 is a perspective view of a radiating fin according to a preferred embodiment of the present invention;

FIG. 3a is an exploded perspective view showing the forming of a radiating fin assembly according to an embodiment of the present invention;

FIG. 3b is an assembled view of FIG. 3a;

FIG. 4 is an assembled perspective view of a thermal module according to a first embodiment of the present invention;

FIG. 5 is an assembled perspective view of a thermal module according to a second embodiment of the present invention; and

FIG. 6 is an assembled perspective view of a thermal module according to a third embodiment of the present invention.

### DETAILED DESCRIPTION OF THE PREFERRED EMBODIMENTS

The present invention directs to a radiating fin and a thermal module formed therefrom, some preferred embodiment thereof will now be described with reference to the accompanying drawings.

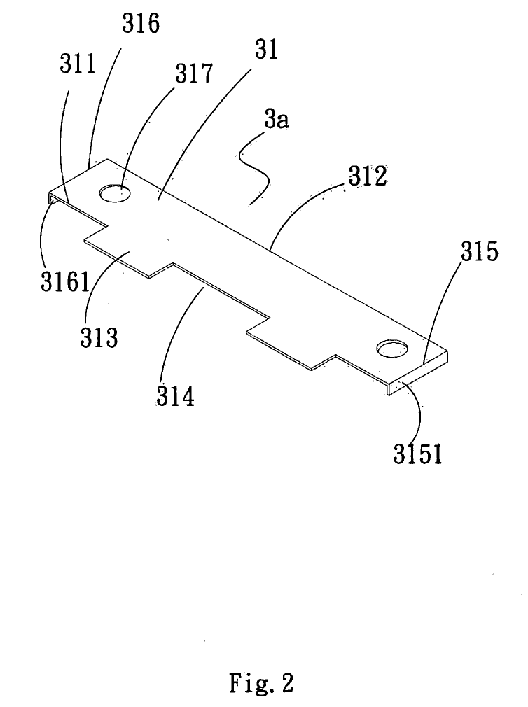

Please refer to FIG. 2 that is a perspective view of a radiating fin 3a according to one embodiment of the present invention. As shown, the radiating fin 3a includes a flat main body 31 having a first transverse edge 311 and a second transverse edge 312. At least one horizontally outward projected portion 313 is provided on anyone of the first and the second transverse edge 311, 312. Of course, the at least one projected portion 313 can also be provided on both of the two transverse edges 311, 312. In the case of more than one projected portion 313 is provided, the projected portions 313 are discontinuously arranged along the first and/or the second transverse edge 311, 312, so that at least one open portion 314 is formed along the first and/or the second transverse edge 311, 312 at a position where the projected portion 313 is not formed.

The main body 31 is provided at two longitudinal ends 315, 316 with a first and a second downward extended skirt portion 3151, 3161, respectively. At least one through hole 317 is formed on the main body 31 for a heat pipe (not shown) to extend therethrough.

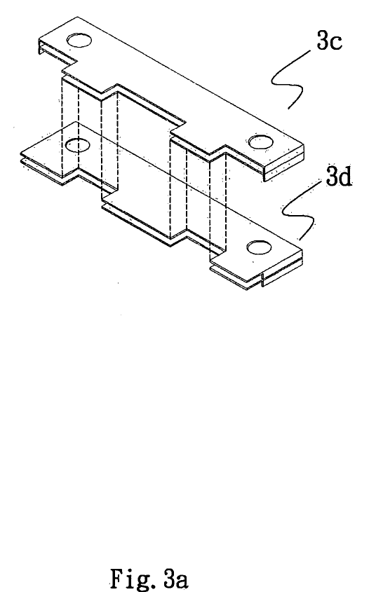

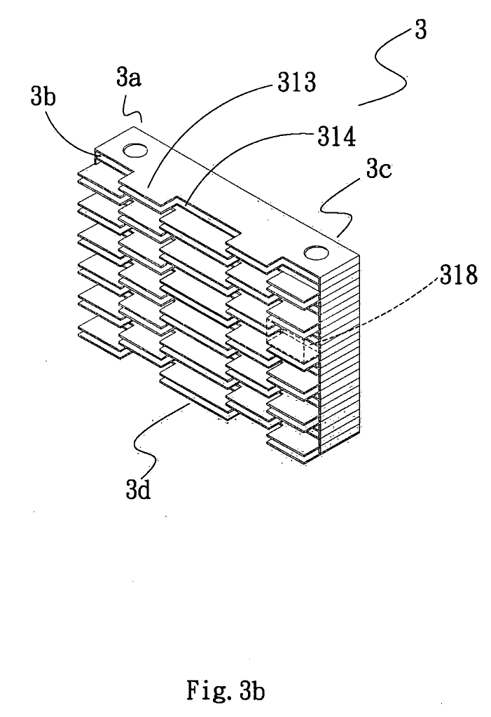

As shown in FIGS. 3a and 3b, a plurality of the radiating fins 3a can be stacked to form a radiating fin assembly 3 with an air passage 3b formed between any two adjacent radiating fins 3a.

The radiating fin assembly 3 shown in FIGS. 3a and 3b consists of a plurality of alternatively arranged first and second radiating fin assemblies 3c, 3d. Each of the first radiating fin assemblies 3c includes a plurality of stacked radiating fins 3a having identical structure. That is, the radiating fins 3a in the first radiating fin assemblies 3c have identical projected portions 313 and identical open portions 314 in number and in position. Similarly, each of the second radiating fin assemblies 3d includes a plurality of stacked radiating fins 3a having identical structure. The radiating fins 3a in the second radiating fin assemblies 3d also have identical projected portions 313 and identical open portions 314 in number and in position. However, the projected portions 313 on the radiating fins 3a in the first and the second radiating fin assemblies 3c, 3d are in a staggered relation to one another, bringing the open portions 314 on the radiating fins 3a in the first radiating fin assemblies 3c and in the second radiating fin assemblies 3d to also be in a staggered relation to one another.

When the first radiating fin assemblies 3c and the second radiating fin assemblies 3d are alternatively arranged to form the radiating fin assembly 3, the projected portions 313 on the first radiating fin assemblies 3c are aligned with the open portions 314 on the second radiating fin assemblies 3d. Since the open portions 314 on the second radiating fin assembly 3d each are located between two projected portions 313 on two first radiating fin assemblies 3c separately located above and below the second radiating fin assembly 3d, a first heat dissipating space 318 larger than the air passage 3b can be formed between two projected portions 313 on two spaced first radiating fin assemblies 3c. Therefore, the radiating fin assembly 3 has a plurality of expanded heat dissipating spaces formed on one or both transverse sides thereof.

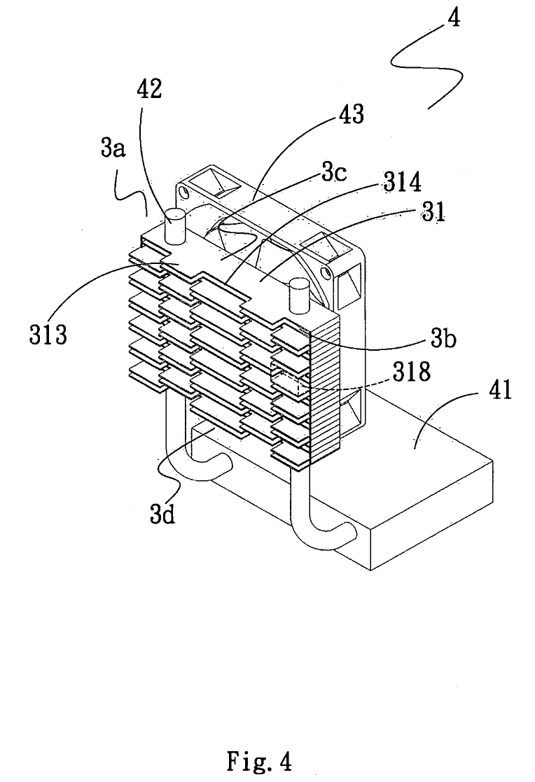

FIG. 4 is an assembled perspective view of a thermal module 4 according to a first embodiment of the present invention. As shown, the thermal module 4 in the first embodiment includes a base 41, at least one heat pipe 42, a fan 43, and a radiating fin assembly 3. The radiating fin assembly 3 includes a plurality of stacked radiating fins 3a. The heat pipe 42 has at least one heat conduction section sequentially extended through the main bodies 31 of the radiating fins 3a to connect the radiating fin assembly 3 to the heat pipe 42, and at least one heat absorption section associated with the base 41. The fan 43 is mounted to a transverse side of the radiating fin assembly 3 for guiding and forcing airflows through the radiating fin assembly 3 to carry away heat absorbed by the radiating fin assembly 3. The base 41 is in direct contact with a heat-producing element (not shown), so that heat produced by the heat-producing element is transferred to the heat pipe 42 via the base 41.

When the fan 43 blows airflows into the air passages 3b in the radiating fin assembly 3 to carry heat away from the radiating fin assembly 3, the heat-carrying airflows flow from one transverse side of the radiating fin assembly 3 toward the other transverse side thereof that is usually provided with the projected portions 313 and accordingly the expanded first heat dissipating spaces 318.

With the expanded first heat dissipating spaces 318, the heat-carrying airflows can more smoothly flow through and out of the radiating fin assembly 3 at increased flowing efficiency, preventing heat from stagnating in the radiating fin assembly 3. Thus, the thermal module 4 can provide upgraded heat dissipating efficiency.

The number and the positions of the projected portions 313 and the open portions 314 on the radiating fin 3a can be varied in many different ways.

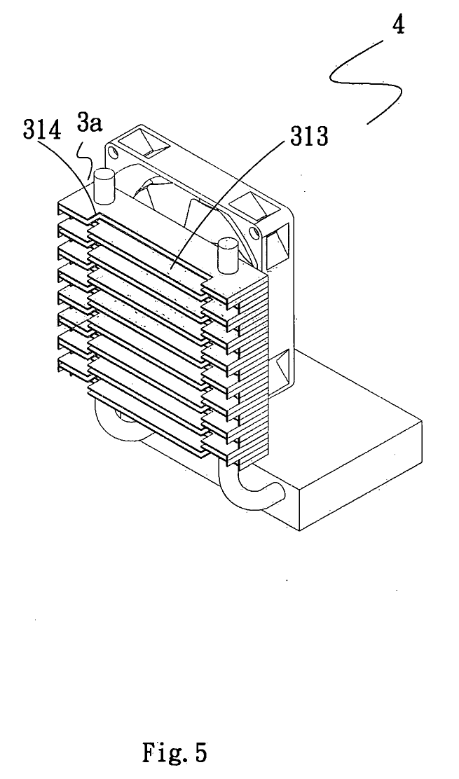

FIG. 5 is an assembled perspective view showing a thermal module 4 according to a second embodiment of the present invention. As shown, in the thermal module 4 of the second embodiment, the radiating fin assembly 3 consists of two types of radiating fins 3a. The projected portions 313 on the first type of radiating fins 3a are aligned with the open portions 314 on the second type of radiating fin 3a, and the number of the projected portions 313 on the first type of radiating fins 3a is the same as that of the open portions 314 on the second type of radiating fins 3a.

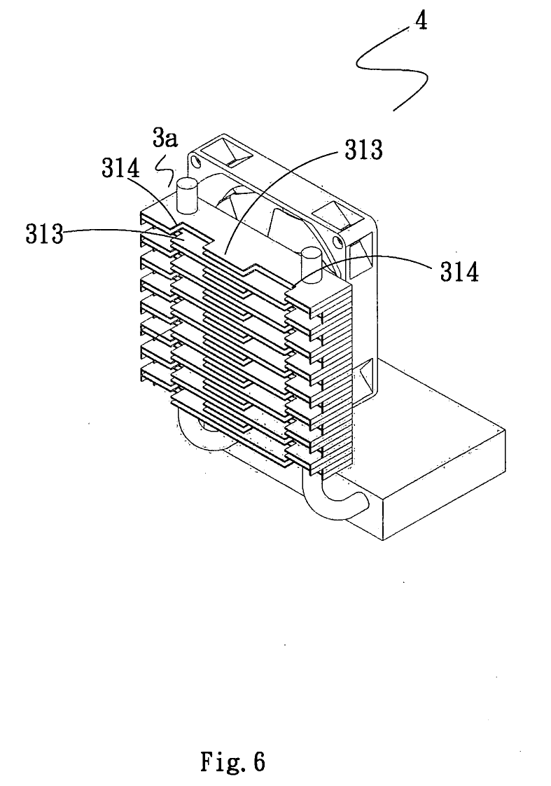

Alternatively, two types of radiating fins 3a having projected portions 313 and open portions 314 in different numbers and positions can be alternately arranged for forming the radiating fin assembly 3. An example of this arrangement is used in a thermal module 4 according to a third embodiment of the present invention shown in FIG. 6. In the third embodiment, the first type of the radiating fins 3a in the radiating fin assembly 3 each have two open portions 314 with one projected portion 313 formed therebetween, and the second type of the radiating fins 3a in the radiating fin assembly 3 each have a widened projected portion 313 located corresponding to the two open portions 314 and the middle projected portion 313 on the first type of radiating fins 3a. In this manner, the thermal module 4 of the third embodiment can also be provided with a plurality of expanded heat dissipating spaces to enable smooth heat-carrying airflows and upgraded heat dissipating effect.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A radiating fin, comprising a flat main body having a first transverse edge and a second transverse edge, and at least one horizontally outward projected portion selectively provided on at least one of the first and the second transverse edge, such that at least one open portion is formed along the first or the second transverse edge at a position where the projected portion is not formed.

2. The radiating fin as claimed in claim 1, wherein the main body is provided on both of the first and the second transverse edge with the at least one projected portion.

3. The radiating fin as claimed in claim 1, wherein the main body is provided at a predetermined position with at least one through hole.

4. The radiating fin as claimed in claim 1, wherein the main body is provided at two longitudinal ends with a first and a second downward extended skirt portion, respectively.

5. A thermal module, comprising:
a base;
a heat pipe including at least one heat absorption section and at least one heat conduction section; and the heat absorption section being associated with the base; and
a radiating fin assembly formed from a plurality of stacked radiating fins; each of the radiating fins including a flat main body having a first transverse edge and a second transverse edge, and at least one horizontally outward projected portion selectively provided on at least one of the first and the second transverse edge, such that at least one open portion is formed along the first or the second transverse edge at a position where the projected portion is not formed; the heat conduction section of the heat pipe being extended through the radiating fin assembly; the at least one projected portion on a first radiating fin in the radiating fin assembly being aligned with the at least one open portion on an adjacent second radiating fin in the radiating fin assembly, so that at least one expanded first heat dissipating space can be formed between two projected portions correspondingly provided on the first radiating fin and a third radiating fin behind the second radiating fin; and the expanded heat dissipating space being selectively formed on at least one of the first and the second transverse edge of the flat main bodies of the radiating fins.

6. The thermal module as claimed in claim 5, wherein the main body of each of the radiating fins is provided on both of the first and the second transverse edge with the at least one projected portion.

7. The thermal module as claimed in claim 5, wherein the main body of each of the radiating fins is provided at a predetermined position with at least one through hole.

8. The thermal module as claimed in claim 5, wherein any two adjacent radiating fins in the radiating fin assembly defines an air passage therebetween.

9. The thermal module as claimed in claim 5, wherein the main body of each of the radiating fins is provided at two longitudinal ends with a first and a second downward extended skirt portion, respectively.

10. The thermal module as claimed in claim 5, further comprising a fan mounted to one side of the radiating fin assembly, wherein the fan can be selectively located adjacent to any one of the first and the second transverse edges of the main bodies.
